(19) United States
(12) Patent Application Publication
(10) Pub. No.: US 2025/0239457 A1
(43) Pub. Date: Jul. 24, 2025

(54) TUNGSTEN-BASED ADDITIVE FOR THROUGH-SUBSTRATE ETCHING

(71) Applicant: Tokyo Electron Limited, Tokyo (JP)

(72) Inventors: Scott Lefevre, Albany, NY (US); Alec Dorfner, Albany, NY (US); Joshua Baillargeon, Albany, NY (US)

(21) Appl. No.: 18/418,849

(22) Filed: Jan. 22, 2024

(51) Int. Cl. H01L 21/308; H01L 21/3065

(52) U.S. Cl. CPC H01L 21/3081; H01L 21/3065

(57) ABSTRACT

A process for adding tungsten during through-substrate etching includes forming a nitride layer over a semiconductor substrate, forming a mask layer over the nitride layer, creating an opening through the mask layer and the nitride layer, exposing the nitride layer to an etch gas comprising tungsten, and extending, with an etch process, the opening through the semiconductor substrate.

### TECHNICAL FIELD

The present disclosure relates generally to semiconductor fabrication, and, in particular embodiments, to tungsten-based additives for through-substrate etching.

### BACKGROUND

Generally, a semiconductor integrated circuit (IC) is fabricated by sequentially depositing a dielectric, conductive, or semiconductor layer over a semiconductor substrate and patterning the layer using photolithography and etch to form electronic and interconnect elements like transistors, resistors, capacitors, metal lines, contacts, and vias in one monolithic structure. At each new technology node, feature sizes are reduced, resulting in increasing the packing density of IC elements to reduce cost. As packing density increases and feature sizes decrease, the ongoing advancement in semiconductor device technology can be constrained by physical limits as compared to prior progress.

Therefore, for further development, the semiconductor industry has embraced three-dimensional (3D) packaging (or 3D integration, hybrid bonding, etc.), such as by stacking multiple semiconductor substrates together using various methods. 3D packaging brings both technological and economic advantages, such as by enabling a mixture of technology nodes to be used in a single final product.

A key aspect in 3D packaging is the ability to form through-substrate openings that are transformed into metallized interconnects for conductive pathways of electrical connections between stacked or bonded semiconductor dies. Such substrate openings, which can include a hole that partially or completely penetrates a substrate, also called a via, can be formed from either side of a die, such as for signal connections and power connections, which may be located on separate sides of a die. One type of high-aspect ratio opening used for 3D packaging are through silicon vias (TSVs) that penetrate the semiconductor substrate and thereby enable short and effective interconnections between stacked dies.

One factor limiting high aspect ratio semiconductor structures can be the use of corrosive etch gases that are used for aggressive deep etches, such as TSVs, but may damage certain other adjacent materials in the process, which is undesirable. For example, materials having a low dielectric constant (i.e., low-k materials) that may include certain nitride materials through which the substrate openings penetrate may be particularly vulnerable to undesired damage during aggressive deep etch processes.

### SUMMARY

In accordance with an embodiment, a process includes forming a nitride layer over a semiconductor substrate; forming a mask layer over the nitride layer; creating an opening through the mask layer and the nitride layer; exposing the nitride layer to an etch gas including tungsten; and extending, with an etch process, the opening through the semiconductor substrate.

In accordance with an embodiment, a process includes providing a plurality of layers, at least some of the layers including a mask layer, a nitride layer under the mask layer, and a silicon-containing layer under the nitride layer; defining an opening in the mask layer; etching the nitride layer through the opening to define first sidewalls of the nitride layer; etching the silicon-containing layer exposed in the opening; and forming a tungsten nitride layer on the first sidewalls of the nitride layer before or during the etching of the silicon-containing layer.

In accordance with an embodiment, a process includes providing a mask layer over a semiconductor substrate including silicon; forming a photoresist layer over the mask layer; creating an opening through the photoresist layer; exposing the mask layer to a gas including tungsten; and extending the opening through the mask layer and the semiconductor substrate.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1A is a depiction of a through-substrate via in one embodiment;

FIG. 1B is a depiction of a through-substrate via in one embodiment;

FIG. 2 is a flowchart describing a through-substrate etching process in one embodiment;

FIG. 3 is a plot of etch rates versus WF₆ flow rates for Si₃N₄ and SiO₂.

FIGS. 4A, 4B, 4C, and 4D are depictions of a substrate stack at various steps in a process for through-substrate etching in one embodiment;

FIGS. 5A and 5B are depictions of a substrate stack at various steps in a process for through-substrate etching in one embodiment;

FIGS. 5C and 5D are depictions of a substrate stack at various steps in a process for through-substrate etching in one embodiment;

FIG. 6A is a depiction of a passivation layer in a process for through-substrate etching in one embodiment;

FIG. 6B is a depiction of a passivation layer in a process for through-substrate etching in one embodiment;

FIG. 6C is a depiction of a passivation layer in a process for through-substrate etching in one embodiment;

FIG. 7 is a flowchart describing a process of adding tungsten during through-substrate etching in one embodiment;

FIG. 8 is a flowchart describing a process of adding tungsten during through-substrate etching in one embodiment;

FIG. 9 is a flowchart describing a process of adding tungsten during through-substrate etching in one embodiment; and

FIG. 10 depicts an etch profile in one embodiment.

### DETAILED DESCRIPTION OF ILLUSTRATIVE EMBODIMENTS

This disclosure describes processes of adding tungsten during through-substrate etching of a semiconductor substrate in various embodiments.

In the following description, details are set forth by way of example to facilitate discussion of the disclosed subject matter. It should be apparent to a person of ordinary skill in the field, however, that the disclosed embodiments are exemplary and not exhaustive of all possible embodiments.

Throughout this disclosure, a hyphenated form of a reference numeral refers to a specific instance of an element and the un-hyphenated form of the reference numeral refers to the element generically or collectively. Thus, as an example (not shown in the drawings), device “12-1” refers to an instance of a device class, which may be referred to collectively as devices “12” and any one of which may be referred to generically as a device “12”. In the figures and the description, like numerals are intended to represent like elements.

As noted above, the semiconductor industry has embraced 3D packaging to enable hybrid devices that stack bonded dies together and can mix different technology nodes in a single final product for economic benefits. The interconnects between bonded semiconductor dies are formed using through-substrate openings that are used for electrical connections between specific locations of the stacked or bonded semiconductor dies. Such substrate openings are holes that can partially or completely penetrate a given substrate layer, and may be referred to as vias with respect to a penetrated layer. One type of high-aspect ratio opening used for 3D packaging are through TSVs that penetrate through the semiconductor substrate and thereby enable short and effective interconnections between stacked and bonded dies. In some embodiments, metallized contact layers can be formed on either side of a die, such as for signal connections and power connections, which may be located on separate sides of a die. Thus, such through-substrate openings can partially or completely penetrate a die substrate and can be used for signal connections or power connections or both.

Various different types of methods may be used to form substrate openings, including deep reactive ion etching (DRIE). TSVs are typically high aspect ratio structures that test the limits of current etching technologies used for such interconnects. In DRIE corrosive etch gases along with an ionized plasma are used for aggressive deep etches, such as TSVs, in an anisotropic manner. Due to the aggressive nature of DRIE, certain other adjacent materials may suffer unintentional damage in the process, which is undesirable. For example, materials having a low dielectric constant (i.e., low-k materials) that include materials used for conductive traces through which the substrate openings penetrate may be particularly vulnerable to undesired damage during DRIE, which is sometimes referred to as a “non-Bosch” process when applied continuously.

In a Bosch etching process, two different process steps may be alternated during etching. A first step may involve DRIE and may last for a first duration. Then, the etching gases are removed and in a second step, passivation is performed by depositing a chemically inert passivation layer for a second duration. Thus, the gases in the etch environment may be rapidly alternated in situ in the Bosch etching process.

To promote the establishment of clean vertical sidewalls at patterned locations, anisotropic etching is used including techniques such as sidewall passivation and ion beam methods. With anisotropic etching, among other techniques, higher aspect ratio features, such as TSVs may be achieved, which is desirable.

TSV technology is a promising technology in three-dimensional packaging that can enable interconnections between stacked ICs, potentially increasing performance, while reducing signal delay and power consumption. TSVs with diameters in the micrometer range may be mainly fabricated by DRIE technology. In particular, the Bosch etch process may be used for high-aspect ratio TSVs, which, as noted above, comprises a cyclical process of an etch cycle followed by a passivation cycle. The Bosch process may involve a plasma etch cycle using the etch gas containing sulfur hexafluoride (SF₆) for etching through silicon substrates that is followed by passivation in the form of deposition of a chemically inert passivation layer, such as by using octafluorocyclobutane (C₄F₈) to deposit the passivation layer, which may be a polymerized layer. The etch and passivation cycles may be alternated after several seconds by switching of the gas environment back and forth between etch gas and deposition gas. During the Bosch process, the passivation layer prevents lateral etching of the substrate while the etching progresses vertically into the substrate. Although the Bosch process is used for high aspect ratio patterning, such as TSV among other deep vertical structures that can reach aspect ratios of 60:1 or greater, certain imperfections or defects may be associated with the alternating gas environment such as scalloping, which may be undesirable.

As noted, continuous etch processes may involve a single etch gas to which the semiconductor substrate is exposed. Such continuous etch processes (also referred to as “non-Bosch” processes) may use similar etch gases as described with the etch cycle in the Bosch process, such as SF₆ for silicon-semiconductor materials, and may be effective for many instances where somewhat lower aspect ratio structures are to be fabricated, such as aspect ratios of 16:1 or even greater.

It has been observed that both Bosch and non-Bosch etch processes may be subject to undesirable secondary effects as higher etch rates are applied, in particular, damage to adjacent low-k materials, such as certain nitrides and nitride-like materials, which is undesirable. The damaged material layer may comprise an organic layer such as spin-on carbon (SOC), amorphous carbon layer (ACL), organic dielectric layer (ODL), and organic planarization layer (OPL). In other embodiments, the damaged material layer may comprise other dielectrics such as silicon nitride, silicon oxide, silicon carbon nitrides, and metal oxides (e.g., aluminum oxide and hafnium oxide) or metals and metalloids such as titanium and titanium nitride, or similar.

As will be described in further detail herein, tungsten may be introduced into the etch process and may protect low-k materials from undesirable damage when aggressive or particularly corrosive etch conditions are being used. In an embodiment, tungsten hexafluoride (WF₆) may be used to introduce tungsten during Bosch and non-Bosch etching processes, such as where SF₆ is used to etch silicon semiconductors. In the Bosch process, tungsten may also be added during the passivation cycle. In some embodiments, tungsten hexachloride WCl₆ or tungsten fluorochloride (WF₃Cl₃) may also be used as a source of tungsten. In particular, the presence of tungsten may promote the formation of a tungsten nitride (WN) passivation layer over the damage-prone materials, which, as discussed above, may be nitrides or nitride-like materials.

Using WF₆ as an additive to introduce tungsten into the etch gas, as described herein, may involve using a small volume fraction of WF₆ with SF₆ in certain embodiments. In some instances, nitrogen (N₂) may also be introduced to promote the deposition of the passivating layer of tungsten nitride, such as to protect the low-k materials, such as materials absent a nitride composition but which may contain Si, O, C, H for example, in the etched stack or adjacent to the etched stack. Using WF₆ as an additive for etch protection, as described herein, may result in selective protection of nitrides and similar materials, while enabling or promoting desirable higher etch rates.

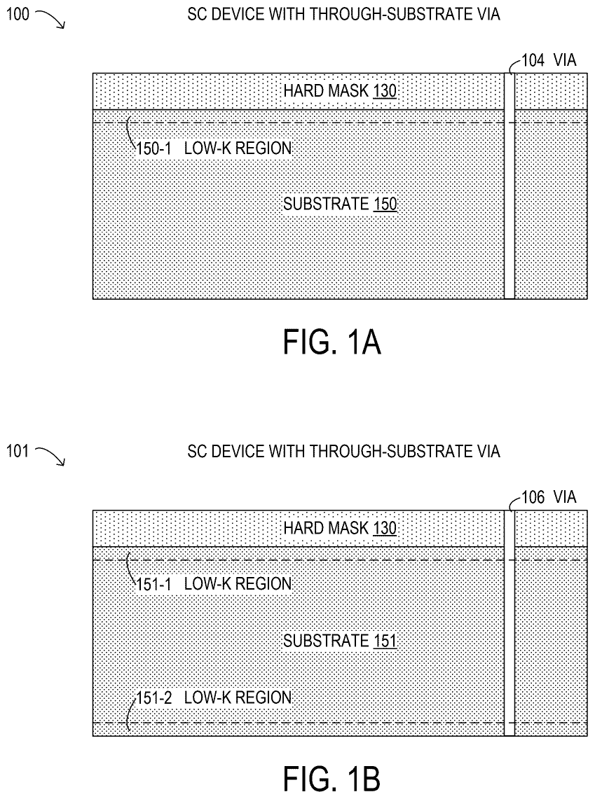

FIG. 1A shows a depiction of a semiconductor device 100 with a through-substrate via 104 in one embodiment. FIG. 1A is a schematic illustration and is not necessarily drawn to scale or perspective. FIG. 1A illustrates a result of a process for forming through-substrate vias using a DRIE process where a tungsten additive was introduced during etching, as described herein. The prior steps in the process are described in further detail below with respect to subsequent figures. It is noted that the arrangement of semiconductor device 100 and through-substrate via 104 is exemplary and is shown in FIG. 1A for purposes of descriptive clarity, and that various different types of semiconductor devices and vias may be used in various embodiments.

As used herein, the terms “via”, “hole”, “opening”, and “void” may be used interchangeably to generally describe a high-aspect ratio void that penetrates into a substrate. In particular, a via is referred to as a hole that penetrates an XY circuit plane to enable interconnections to another XY circuit plane at a different Z elevation. Thus, the term TSV refers to deep vias that penetrate through a semiconductor substrate, such as via 104 penetrates substrate 150 to enable interconnections to a second semiconductor substrate (not shown).

In semiconductor device 100 of FIG. 1A, a hard mask layer 130 is shown over a substrate 150. In some embodiments, the material for hard mask layer 130 may comprise a nitride or a nitride-like material, a silicon layer, a silicon oxynitride, and others. Although hard mask layer 130 is shown covering substrate 150 (and substrate 151 in FIG. 1B discussed below), in various embodiments, additional layers may be present between hard mask layer 130 and substrate 150, 151. For example, a soft mask layer (not shown) may be present underneath hard mask layer 130 and covering substrate 150, 151 in some embodiments. The soft mask layer may include dielectric materials, among others, and may not directly contribute to masking during DRIE.

Substrate 150 may collectively represent various other layers associated with an IC, such as inter level dielectric layers comprising various interconnects, etch stop layers, as well as semiconductor layers formed over an initial substrate that may include a single crystal semiconductor. The initial substrate may comprise bulk silicon, epitaxial silicon over bulk silicon, gallium arsenide, silicon carbide, germanium, silicon on insulator (SOI), or hetero-structures such as gallium nitride on silicon, silicon on sapphire, and the like, and may further include epitaxially grown embedded semiconductor regions such as embedded silicon germanium. As shown in FIG. 1A, substrate 150 may include a low-k region 150-1 at a top portion adjacent to hard mask layer 130. In the configuration shown for exemplary semiconductor device 100, low-k region 150-1 may represent an area where IC elements have been formed and where certain low-k materials are expected along the etch path for via 104. The low-k region 150-1 may comprise several inter level dielectric layers comprising various interconnects and accordingly a multilevel metallization layer in one example. It is noted that the etch path configuration with respect to low-k regions may be different than depicted in FIG. 1A in various embodiments. For example, a low-k region may be present adjacent to an opposite surface of substrate 150 from hard mask layer 130. In some embodiments, both surfaces of substrate 150 may have low-k regions (see FIG. 1B), which may be respectively passivated with tungsten additive to the etch gas, as described herein.

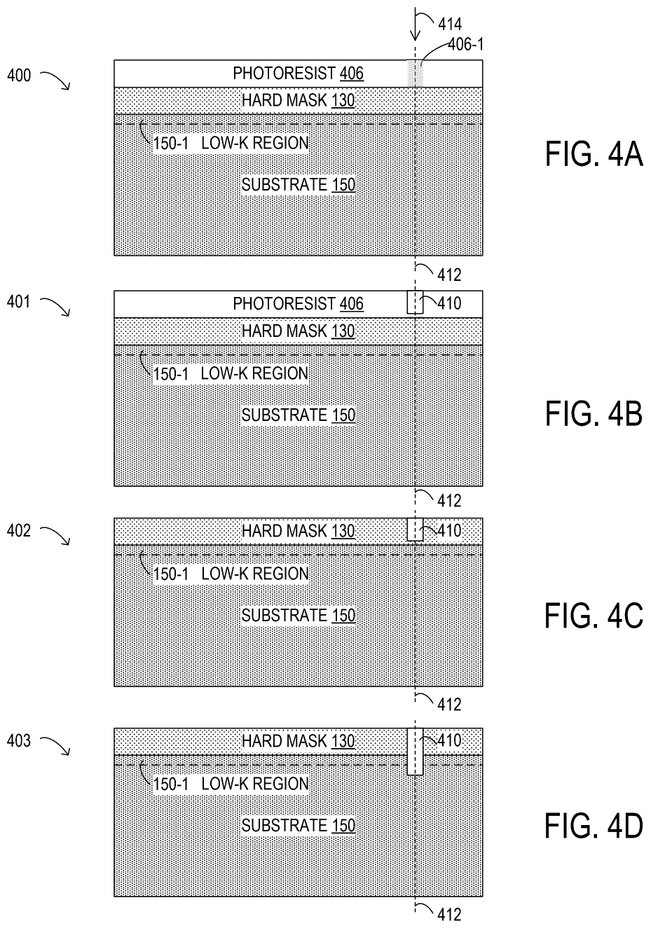

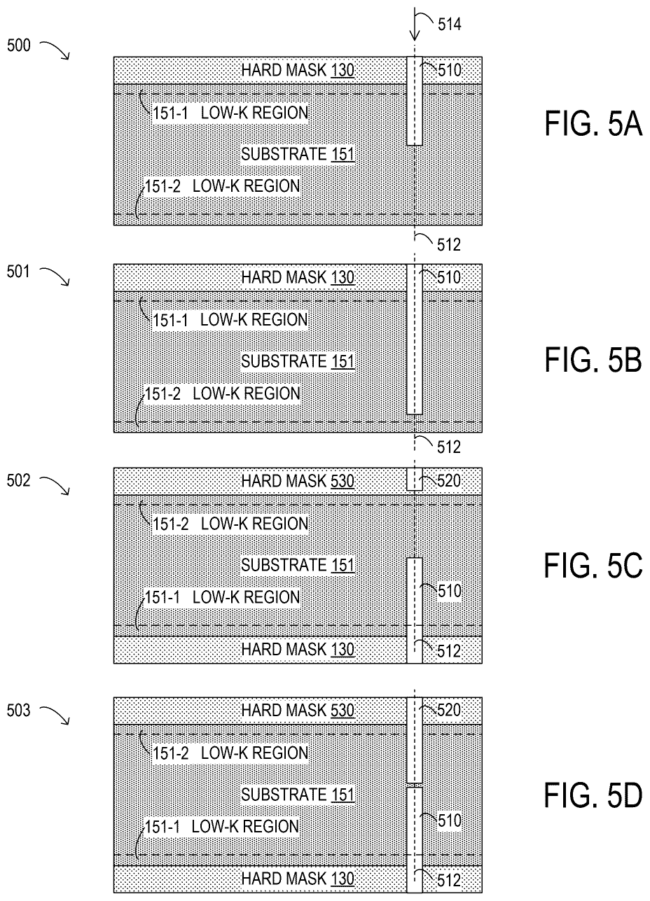

It is further noted that, while an etch path originating above hard mask layer 130 and penetrating downwards through substrate 150 is shown and described herein, different types of etch paths may be implemented in different embodiments. In various embodiments discussed herein, TSVs may be formed from the front side or active side of substrate 150 or from the back side of substrate 150. For example, low-k region 150-1 may include semiconductor device regions as well as metallization layers including interconnects. In low-k region 150-1, the metallization layers may include several layers of inter level dielectric materials, many of which may have a low-k materials that are less immune to the corrosive etch chemistry used in forming TSVs. In the case of a front side TSV etch process, after forming a protective passivation layer over substrate 150, hard mask layer 130 and a photoresist layer 306 (see also FIG. 4A) may be formed. In case of a back side TSV etch process, in one example, after forming the device regions and the metallization layers at low-k region 150-1, substrate 150 may be thinned from the back side to expose the back side of substrate 150, after which a hard mask and a photoresist layer may be formed on the exposed back side of substrate 150 (see also FIGS. 5C and 5D).

In some embodiments, a TSV may be formed using two partial etch paths, each originating at an opposing face of substrate 150 (see FIGS. 5C and 5D). The use of two partial etch paths may be economical when an etch rate declines substantially over the distance of the etch path, such as for high-aspect ratio TSVs. Then, an overall time savings may result by stopping a first partial etch about half-way along the TSV etch path, removing the substrate and restarting the etch process from the opposing face to form a second partial etch that meets the first partial etch in the middle of the substrate. When using two opposing etch paths, the two etch fronts are subject to alignment with each other, which may make such an embodiment more feasible for TSV having a larger diameter, for example.

In various etch path configurations, including the top-down etch path shown and described below with respect to subsequent figures, a location of low-k region 150-1 may be known in advance along with an expected etch rate. Accordingly, a timing of progress along the etch path may enable introducing tungsten to the etch gas before or immediately upon the etch path reaching low-k region 150-1, in different embodiments, as will be described in further detail below. In this manner, formation of passivating tungsten nitride along the sidewalls may be initiated prior to the etch path reaching low-k region 150-1 and during etching of low-k region 150-1. Then, after low-k region 150-1 has been penetrated by the etch and the etch path proceeds into substrate 150, tungsten can be removed from the etch gas. Similarly, nitrogen may be added to the etch gas to promote the formation of a passivating tungsten nitride surface layer on the sidewalls, as will be described in further detail As a result of the timely addition and removal of tungsten or nitrogen or both during etching, the tungsten nitride passivation layer can protect a photoresist layer, hard mask layer 130, low-k region 150-1, 151-1, 151-2 (see FIG. 1B), or various combinations thereof, during the subsequent etch process, as the etch path proceeds to complete via 104.

In FIG. 1B, a depiction of a semiconductor device 101 with a through-substrate via 106 is shown in one embodiment. FIG. 1B is a schematic illustration and is not necessarily drawn to scale or perspective. Semiconductor device 101 is similar to semiconductor device 100 shown and described above with respect to FIG. 1A. In semiconductor device 101, a substrate 151 is shown having low-k region 151-1 at a top face and a low-k region 151-2 at a bottom face. Low-k region 151-2 may represent a metallized power redistribution layer for providing contact pads for the connection of a voltage supply (Vdd) and a ground for the IC devices that are formed in low-k region 150-1, in particular embodiments.

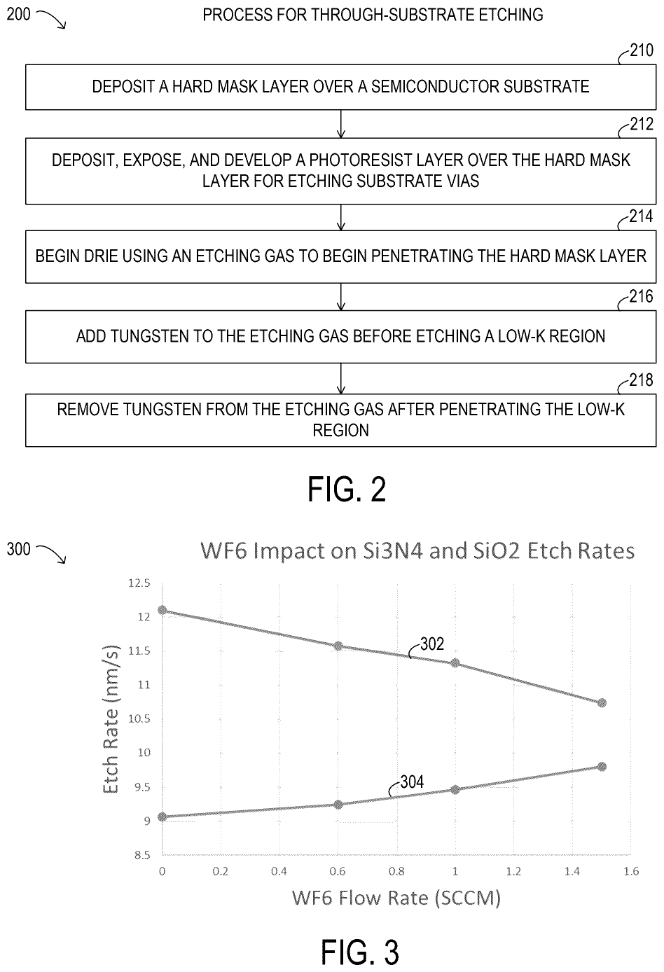

Turning now to FIG. 2, a process 200 for through-substrate etching, or simply process 200, is shown in flowchart format. It is noted that some portions of process 200 may be omitted or rearranged in certain embodiments. Process 200 may be used to form via 104, as also described in cross-sectional views of semiconductor device 100 at various intermediate stages of processing, illustrated in FIGS. 4A-4D, resulting in semiconductor device 100 shown in FIG. 1A, for example.

As shown, process 200 may begin at step 210 by depositing a hard mask layer over a semiconductor substrate. As noted, the semiconductor substrate may represent various structures, layers, materials used to form a semiconductor device, such as substrate 150 shown in FIGS. 1A and 5C, for example. At step 212, a photoresist layer is deposited, exposed, and developed over the hard mask layer for etching substrate vias. The photoresist layer formed in step 212 may provide one or more locations for forming respective vias, represented by via 104, which is shown as a single example via for descriptive clarity. In FIG. 4A, described below, a patterned and developed location on a photoresist layer is shown. At step 214, DRIE begins using an etching gas to begin penetrating the hard mask layer. DRIE is used as an anisotropic etch process that is able to etch high-aspect ratio holes and vias, typically in a direction normal to the face of a substrate where the hard mask was deposited. At step 216, tungsten is added to the etching gas before etching a low-k region. At step 218, the tungsten is removed from the etching gas after penetrating the low-k region. In some embodiments, as will be described in further detail below, tungsten may be added to the etch gas prior to step 214 and may be continuously added during the etch process, such that steps 216 and 218 may be modified or omitted. In some embodiments, tungsten, either with or without nitrogen, may be added and removed from the etch gas at certain points in the etch process, as described herein. As etching proceeds, the aspect ratio of the via increases, which is realized by using WF₆ as an additive for etch protection, as described herein.

In FIG. 3 a plot 300 of etch rate versus WF₆ flow rate in units of standard cubic centimeters per minute (SCCM) is shown for Si₃N₄ 302 and SiO₂ 304. For example, hard mask layer 130 may comprise Si₃N₄ while at least some portions of substrate 150, such as some portions of low-k region 150-1, may comprise SiO₂ 304.

As noted, the etch gas used for DRIE may include SF₆ and O₂ to which WF6 is added. The addition of WF6 to the etch gas may enable the following Reactions 1-5 to occur during DRIE. It is noted that during DRIE, which may result in high energy local conditions along the etch path, it may be assumed that reaction kinetics do not significantly hinder the following Reactions 1-5 and that the following Reactions 1-5 are largely governed by the standard Gibbs free energy change, ΔG°, that indicates the thermodynamic favorability or unfavorability of a given reaction. Since, as listed below, the Gibbs free energy ΔG° is less than zero or negative for each of Reactions 1-5, Reactions 1-5 are thermodynamically favored to a degree indicated by a respective magnitude of ΔG°. In Reactions 1-5 below, the DRIE reaction conditions for ΔG° are given in units of kilojoule per mole (kJ/mol) for 150 C temperature and 10 mT magnetic field.

2WF₆(g)+SiO₂↔2WOF₄(g)+SiF₄(g) ΔG°=−70.58 kJ/mol [Reaction 1]

WF₆(g)+SiO₂↔WO₂F₂(g)+SiF₄(g) ΔG°=−149.38 kJ/mol [Reaction 2]

4WF₆(g)+3SiO₂↔2WOF₄(g)+2WO₂F₂(g)+3SiF₄(g) ΔG°=−369.34 kJ/mol [Reaction 3]

2WF₆(g)+3SiO₂↔2WO₃+3SiF₄(g) ΔG°=−478.56 kJ/mol [Reaction 4]

2WF₆(g)+Si₃N₄↔W₂N+3SiF₄(g)+1.5N₂(g)ΔG°=−1023.47 kJ/mol [Reaction 5]

Reactions 1-4 show that consumption of SiO₂ in the presence of WF₆ is favorable thermodynamically and may increase as a concentration of WF₆ is increased, as given by curve 304 for SiO₂ in plot 300 of FIG. 3. Reaction 5 shows that consumption of Si₃N₄ is more favorable than Reactions 1-4, as given by the larger magnitude of ΔG°=−1023.47 kJ/mol for Reaction 5 as compared with Reactions 1-4. For example, when hard mask layer 130 is comprised of or consists of Si₃N₄, Reaction 5 indicates that consumption of Si₃N₄ by reaction with WF₆ is significantly favorable and results in formation of W₂N species that can form a passivation layer that effectively replaces at least some of the Si₃N₄ that is consumed. In this case, consumption of Si₃N₄ provides a source of nitrogen for the W₂N passivation layer and also released additional N₂ gas, which also can, in turn, react with WF₆ under DRIE conditions to form tungsten nitride passivation species locally at the sidewalls. Accordingly, such processes that favor formation of tungsten nitride passivation layers, as given by Reaction 5, contribute to the reduction of etch rate of the remaining Si₃N₄ that is shown in curve 302, indicating a decrease in the etch rate for Si₃N₄ as WF₆ concentration (reflected by WF₆ flow rate in plot 300) is increased.

Plot 300 shows a decrease in etch rate as WF₆ flow rate increases for Si₃N₄ 302 with a corresponding increase in etch rate for SiO₂ 304. Accordingly, plot 300 may reflect a positive selectivity for nitride-like materials for which the most protection is indicated for TSV processes by tungsten nitride passivation. The slowing of etch rate for Si₃N₄ 302 shows etch protection that is desirable for Si₃N₄ 302 with the addition of WF₆ to the etch gas. Furthermore, plot 300 shows that, as passivation occurs for Si₃N₄ 302 and its etch rate decreases, a corresponding increase in etch rate for SiO₂ 304 may be observed, which may be a result of increased local etchant gas availability due to passivation of Si₃N₄ 302 that would otherwise also consume etchant gas, including WF₆. Furthermore, Reaction 4 may also indicate formation of another potential passivation layer species, WO₃, that may be deposited at the sidewalls in the absence of nitrogen but in the presence of tungsten in the etch gas under DRIE conditions.

Referring now to FIGS. 4A-4D, various cross-sectional depictions show states of a semiconductor device during steps corresponding to certain portions of process 200 as shown in FIG. 2. In FIGS. 4A-4D, an etch path 412 shows where a via 410 is to be etched, while arrow 414 shows a direction of ion acceleration for DRIE that is normal or perpendicular to a surface of the semiconductor device. Accordingly, in FIGS. 4A-4D, anisotropic DRIE is depicted as given by etch path 412 in direction 414, while the flow and composition of etch gases is also controlled (not shown). In particular, FIGS. 4A-4D depict DRIE etching of via 410 for a semiconductor device having a low-k region at one face, corresponding to semiconductor device 100 in FIG. 1A having substrate 150.

In some embodiments, etch processes indicated in steps 214, 216, and 218 of FIG. 2, may be performed using, for example, a Bosch process, or a continuous plasma etch, such as a non-Bosch process. When aggressive or corrosive etchant gases such as SF₆ are used, whether in a Bosch process or a non-Bosch process, a certain volume fraction of WF₆ may be added to the etchant gas or the passivation gas as a source of tungsten, as described in various embodiments herein. The effect of the WF₆ may be to add a passivation layer of tungsten nitride along the sidewalls of a partial via, such as via 410. Thus, steps 214, 216, and 218 of FIG. 2 may include using WF₆ additive for etch protection, as described herein, such as resulting in semiconductor device 100 in FIG. 1 having via 104, which represents a high aspect ratio TSV.

The passivation of the sidewalls of partial via 410 using WF₆ as an additive to the etch gas may occur as a result of tungsten nitride deposition during exposure of the etchant gas. As described, the tungsten nitride deposition may selectively occur on sidewalls of partial via 410 to protect low-k region 150-1 having materials that may have an affinity for tungsten or tungsten nitride, which is desirable for promoting higher aspect ratio etches without undesired damage or other negative secondary effects. Thus, the tungsten nitride deposition resulting from the introduction of tungsten by WF₆, along with nitrogen, may protect the low-k material in low-k region 150-1. The passivation may be particularly beneficial in preventing damage to the low-k materials during an aggressive high-aspect ratio etch process that may endure for some time after the tungsten nitride passivation layer is formed to protect low-k region 150-1. For example, a volumetric concentration of 0.5%, 1%, 1.5%, 2%, 2.5%, 3%, as non-limiting concentrations among other concentrations, with respect to a flow rate of WF₆ in the etch gas or the passivation gas may be used in particular embodiments. In some cases, volumetric flow concentrations of between 0.2% and 0.5%, between 0.5% and 1%, or between 1% and 2% WF₆, as non-limiting ranges among other possible ranges, may be used in the etch gas or the passivation gas. In terms of flow rate as measured in SCCM, in various examples, a flow rate of 1, 2, 3, 4, 5, or 6 SCCM may be used for the etch gas or the passivation gas. In particular embodiments, a flow rate between 0.1 and 1.0 SCCM, between 0.5 and 1.5 SCCM, or between 1.0 and 1.5 SCCM may be used for the etch gas or the passivation gas.

As noted, the use of WF₆ as an additive for etch protection during through-substrate etching may further include starting and stopping the addition of WF₆, along with starting and stopping the addition of nitrogen gas, at certain judicious times during the etch process, as will be described in further detail below. For example, WF₆ additive to the etch gas along with nitrogen may be introduced prior to or during etching of low-k region 150-1 that may be particularly susceptible to damage during etching. In some embodiments, the WF₆ additive to the etch gas may continue, such as with or without nitrogen in various embodiments, as the etch process goes deeper into substrate 150 along etch path 412. In particular embodiments, WF₆ along with nitrogen is removed from the etch gas after the etch process proceeds through low-k region 150-1.

As noted, nitrogen (N₂) gas may be added to the gas environment during the addition of WF₆ additive to the etch gas, to promote the formation of tungsten nitride as a passivating agent at the exposed sidewalls of partial via 410 that are subject to damage upon further exposure to primary etch gases, such as SF₆. Additionally, tungsten nitride may be formed at sidewalls of photoresist layer 406 using WF₆ additive to the etch gas along with nitrogen for etch protection, as described below. For example, N₂ gas may be flowed at around 20% by volume while WF₆ may be flowed at less than 1% by volume in particular embodiments. In certain instances, N₂ may be used when WF₆ is used as an additive for etch protection and also when SiF₄ is used in the etch gas, such as in place of a fluorinated oxide, or in addition to a mixture of SF₆ and O₂.

Various other benefits may be achieved by using WF₆ as an additive for etch protection to introduce tungsten during etching, as described herein. For example, certain non-Bosch processes may be constrained in the aspect ratio that is attainable without WF₆ additive. Using WF₆ additive for etch protection, as described herein, may enable higher aspect ratios to be formed using non-Bosch processes, such as high aspect ratio etching of Si or TSVs, due to the additional sidewall passivation by formation of tungsten nitride that can occur in the presence of WF₆ additive in the etch gas, along with nitrogen. In this manner, a longer etch process duration may be enabled by the protection of low-k region 150-1 from the sidewall passivation, thereby enabling longer or higher aspect ratio vias to be etched.

In FIG. 4A, a stack 400 is shown after deposition of a photoresist layer 406 over a hard mask layer 130, such as by spin coating and subsequent curing. In stack 400, a location 406-1 indicates a location of photoresist layer 406 that has been patterned and developed and is more susceptible to removal by DRIE than remaining portions of photoresist layer 406. Although a singular location 406-1 and a singular via 410 at location 406-1 is shown in FIGS. 4A-4D for descriptive clarity, it will be understood that multiple locations and vias may be concurrently etched by DRIE in various embodiments.

In FIG. 4B, a stack 401 shows progress of via 410 by DRIE partially into photoresist layer 406 along etch path 412. For the etching process in stack 401 along etch path 412, the etch gas may be controlled to include no tungsten and no nitrogen, tungsten without nitrogen, or tungsten with nitrogen, in various embodiments. For example, when no additional passivation along the sidewalls of photoresist layer 406 is desired, the etch gas used for stack 401 may include no tungsten and no nitrogen, such as by primarily including a mixture of SF₆ and O₂ in particular embodiments. In another example where passivation of the sidewalls of photoresist layer 406 by a tungsten nitride species is desired, tungsten with nitrogen may be added to the etch gas prior to beginning DRIE or during DRIE of photoresist layer 406. The tungsten nitride passivation layer may be formed by the reaction of a tungsten precursor with a nitrogen precursor gas such as N₂. It is noted that portions of photoresist layer 406 other than portion 406-1 are also consumed by DRIE and that photoresist layer 406 is removed as DRIE along etch path 412 progresses (see also FIGS. 4C, 4D). In yet another example where passivation by a tungsten nitride species at the sidewalls of via 410 formed by DRIE through hard mask layer 130 is desired, as described herein, tungsten alone without nitrogen may be added to the etch gas prior to etch path 412 reaching hard mask layer 130, such as at a depth of via 410 shown in stack 401 in FIG. 4B, which may enable Reaction 5 to proceed as soon as hard mask layer 130 is exposed along etch path 412.

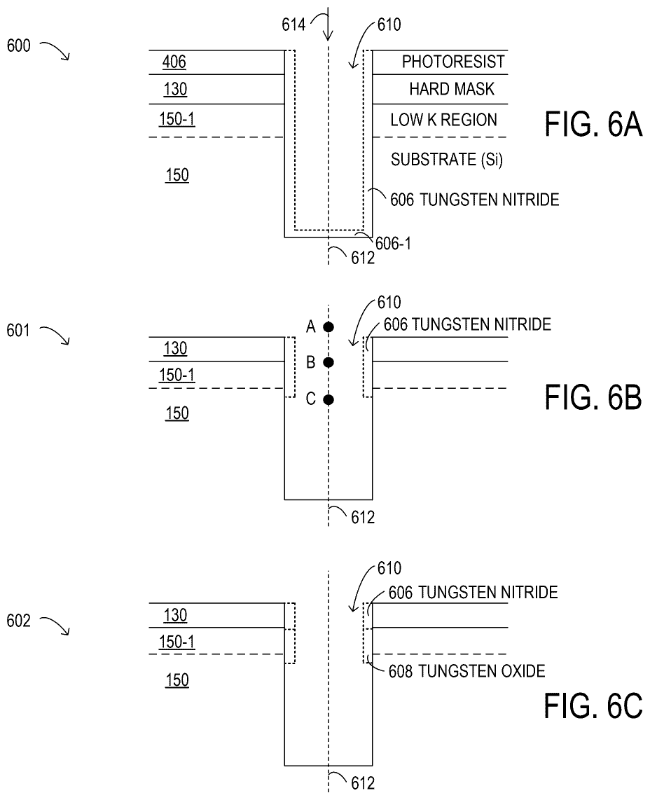

In FIG. 4C, a stack 402 shows progress of via 410 by DRIE partially into hard mask layer 130 along etch path 412. In stack 402, it is assumed that photoresist layer 406 has been entirely consumed by DRIE and is no longer present, but that via 410 was previously initiated at the desired location along etch path 412 and continues to progress along etch path 412. When tungsten is added to the etch gas prior to etch path 412 progressing into hard mask layer 130, a tungsten nitride passivation layer (not shown in FIG. 4C, see FIGS. 6A-6C) may be formed along the sidewalls of via 410 at hard mask layer 130, for example, as given by Reaction 5 among other possible reactions to form tungsten nitride species. Furthermore, as etch path 412 approaches or begins to penetrate into low-k region 150-1, nitrogen may also be included with the etch gas in addition to tungsten. In some embodiments, both tungsten and nitrogen may be added to the etch gas earlier as etch path 412 approaches hard mask layer 130 and the addition of both tungsten and nitrogen to the etch gas may be continued as etch path 412 progresses into low-k region 150-1. In particular embodiments, tungsten alone may be continued as etch path 412 progresses into low-k region 150-1 and may result in a passivation layer of tungsten oxide (instead of tungsten nitride) along the sidewalls of low-k region 150-1 in the absence of additional nitrogen, such as by consuming SiO₂ that may be present in low-k region 150-1, as given by Reaction 4.

In FIG. 4D, a stack 403 shows progress of via 410 by DRIE through low-k region 150-1 along etch path 412. In certain embodiments where via 410 is formed for the purposes of providing interconnections to IC elements in low-k region 150-1 to a top surface of stack 403 as shown in FIG. 4D, etch path 412 may terminate at the depth shown of via 410 in FIG. 4C. In other embodiments where via 410 is etched further to form a TSV, etch path 412 may continue until substrate 150 is penetrated, and may result in the TSV shown by via 104 in FIG. 1A. When additional sidewall passivation is desired, such as to enable formation of a higher aspect ratio TSV using a non-Bosch process, both tungsten and nitrogen may be added to the etch gas along the remaining portions of etch path 412 to form a tungsten nitride species passivation layer at the sidewalls. The tungsten nitride passivation layer may be formed by the reaction of a tungsten precursor with a nitrogen precursor gas such as N₂.

Referring now to FIGS. 5A-5D, various cross-sectional depictions show states of a semiconductor device during steps corresponding to certain portions of process 200 as shown in FIG. 2. In FIGS. 5A-5D, an etch path 512 shows where a via 510 is to be etched, while arrow 514 shows a direction of ion acceleration for DRIE that is normal or perpendicular to a surface of the semiconductor device. Accordingly, in FIGS. 5A-5D, anisotropic DRIE is depicted as given by etch path 512 in direction 514, as explained below, while the flow and composition of etch gases is also controlled (not shown). In particular, FIGS. 5A-5D depict DRIE etching of via 510 as a TSV for a semiconductor device having a low-k region at each top and bottom face, corresponding to semiconductor device 101 in FIG. 1B having substrate 151.

In FIG. 5A, via 510 is shown penetrating about halfway through substrate 151 of a stack 500, such as according to the process described above with respect to FIGS. 4A-4D with substrate 150. Substrate 151 in stack 500 includes low-k region 151-2, shown at a bottom face in FIG. 5A. As noted above, when passivation of sidewalls of via 510 is desired along etch path 512, both tungsten and nitrogen may be added to the etch gas (not shown) during DRIE of via 510, or the addition of tungsten and nitrogen to the etch gas may be continued when previously initiated. In some embodiments, no tungsten and no nitrogen are added to the etch gas for portions of etch path 512 passing through bulk portions of substrate 151, and no sidewall passivation with tungsten nitride species is used.

In FIG. 5B, via 510 is shown penetrating further through substrate 151 of a stack 501, as via 510 approaches low-k region 151-2 along etch path 512. Stack 501 may accordingly represent a continuation of the etch process described above with respect to stack 500 in FIG. 5A. As etch path 512 approaches low-k region 151-2 in stack 501, both tungsten and nitrogen may be added to the etch gas (if not already included in the etch gas) to provide a tungsten nitride passivation layer at the sidewalls of via 510 as via 510 penetrates low-k region 151-2. When via 510 penetrates substrate 151 in stack 501, a TSV corresponding to via 106 in semiconductor device 101 in FIG. 1B may be formed.

In FIGS. 5C and 5D, another embodiment of an etch process is shown from the state of via 510 shown in stack 500 of FIG. 1A. Specifically, in a stack 502 of FIG. 5C, substrate 151 has been flipped after via 510 was formed about half-way through substrate 151, such that low-k region 151-2 is at a top face of substrate 151. Additionally, a hard mask layer 530 has been formed over low-k region 151-2. In stack 502, prior steps of forming and developing a photoresist layer and initiating etching of a via 520 into hard mask layer 530 at etch path 512 are assumed and have been omitted for descriptive clarity. Accordingly, via 520 in stack 502 may correspond to via 410 in stack 402 (see FIG. 4C), as described above. Accordingly, for example, tungsten and nitrogen may be added to the etch gas for via 520 in stack 502 prior to etch path 512 reaching low-k region 151-2, as described above, in order to form a tungsten nitride species passivation layer at the sidewalls of via 520. In FIG. 5D, via 520 is shown progressing along etch path 512 until via 520 meets via 510 at some point along etch path 512 within substrate 151 to form the TSV. It is noted that due to alignment issues, the etch process shown in FIGS. 5C and 5D may be performed for vias 510, 520 having an internal radius greater than a minimum radius in some embodiments. When via 520 reaches via 510 in stack 503, the TSV corresponding to via 106 in semiconductor device 101 in FIG. 1B may be formed.

Referring now to FIGS. 6A-6C, various enlarged cross-sectional depictions show states of a semiconductor device during steps corresponding to certain portions of process 200 as shown in FIG. 2, including a depiction of a passivation layer 606 in a process for through-substrate etching, as described herein. In FIGS. 6A-6C, an etch path 612 shows where a via 610 is to be etched, while arrow 614 shows a direction of ion acceleration for DRIE that is normal or perpendicular to a surface of the semiconductor device. Accordingly, in FIGS. 6A-6C, anisotropic DRIE is depicted as given by etch path 612 in direction 614, as explained below, while the flow and composition of etch gases is also controlled (not shown). In particular, FIGS. 6A-6C depict formation of passivation layer 606 that includes tungsten nitride species formed during DRIE etching of via 610.

In FIG. 6A, a stack 600 is depicted corresponding to stack 401 in FIG. 4B. It is noted that stack 600 may vary as via 610 progresses along etch path 612 using DRIE and that layers shown in stack 600 are depicted to illustrate layers of stack 600 generally and not necessarily at a given depth of via 610 or at the shown depth in FIG. 6C. Stack 600 is shown as an example of continuous formation of passivation layer 606 during DRIE of via 610 in which a tungsten precursor, such as WF₆, and a nitrogen precursor, such as N₂, are continuously added to the etch gas. Thus, in stack 600, passivation layer 606 may be formed along each layer in stack 600, including photoresist layer 406 (when present), hard mask layer 130, low-k region 150-1, as well as bulk portions of substrate 150. It is noted that passivation layer 606-1 formed at the bottom surface of via 610 may be continuously removed by DRIE when formed, which enables ongoing progress of via 610 along etch path 612.

In FIG. 6B, a stack 601 is depicted corresponding to stack 402 in FIG. 4C. Stack 601 is shown as an example of formation of passivation layer 606 at particular locations during DRIE of via 610 in which a tungsten precursor, such as WF₆, and a nitrogen precursor, such as N₂, are added and removed from the etch gas at different times. Specifically, in stack 601, prior to via 610 reaching point A or at point A along etch path 612, a tungsten precursor may be added to the etch gas. For example, when WF₆ with or without nitrogen is added to the etch gas at point A along etch path 612, formation of passivation layer 606 at hard mask layer 130 may occur, such as according to Reaction 5. Then, at point B along etch path 612, nitrogen may be added to the tungsten precursor if not already being added to the etch gas. As a result of both tungsten and nitrogen being added to the etch gas, formation of passivation layer 606 may continue from hard mask layer 130 through low-k region 150-1. Then, at point C along etch path 612, tungsten or nitrogen or both may be removed from the etch gas to stop formation of passivation layer 606, as shown in stack 601. Passivation layer 606, as shown in stack 601, may provide desired passivation and protection of hard mask layer 150 and low-k region 150-1 for the purposes of etching via 610, even after formation of passivation layer 606 ends along etch path 612.

In FIG. 6C, a stack 602 is depicted corresponding to stack 402 in FIG. 4C. Stack 602 is shown as an example of formation of passivation layer 606 and a passivation layer 608 at particular locations during DRIE of via 610 in which a tungsten precursor, such as WF₆, is added to the etch gas without the addition of nitrogen. Specifically, in stack 602, the presence of WF6 in the etch gas may enable formation of passivation layer 606 over hard mask layer 130 at sidewalls of via 610 without the addition of nitrogen, such as given by Reaction 5. In this case, a surface portion of hard mask layer 130 that includes Si₃N₄ may be consumed according to Reaction 5 and may provide nitrogen to form tungsten nitride as passivation layer 606 in stack 602. As via 610 proceeds along etch path 612 to low-k region 150-1 in stack 602, tungsten oxide as given by Reaction 4 may be deposited as passivation layer 608 that includes tungsten oxide. After passivation layer 608 is formed at sidewalls of low-k region 150-1, the addition of tungsten to the etch gas is stopped in stack 602 and no further passivation layer is formed along etch path 612.

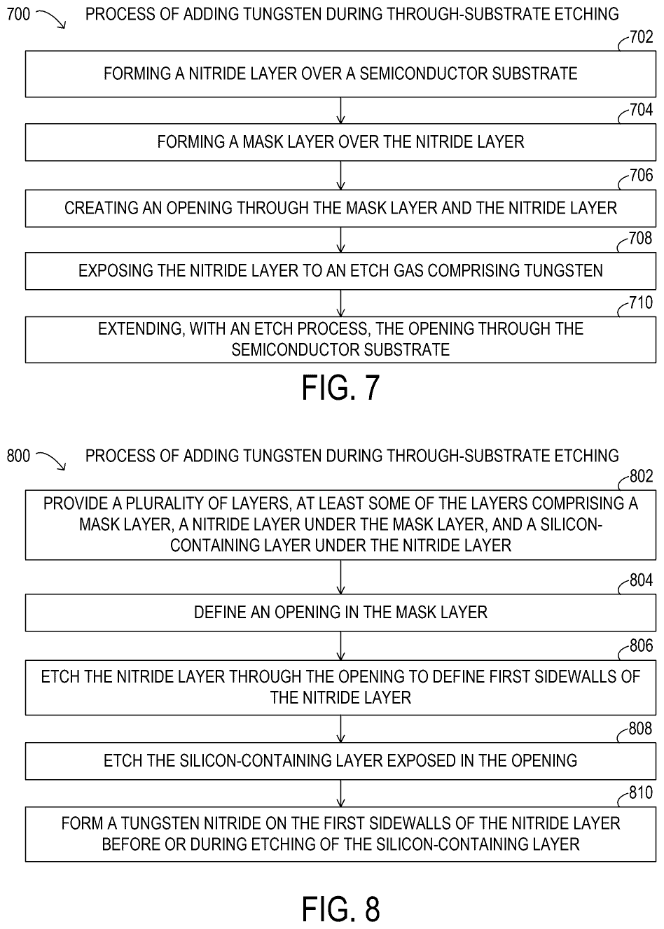

Turning now to FIG. 7, a process 700 of adding tungsten during through-substrate etching is shown in flowchart format. It is noted that some portions of process 700 may be omitted or rearranged in certain embodiments.

Process 700 may begin at step 702 by forming a nitride layer over a semiconductor substrate. For example, substrate 150 may be a silicon-containing semiconductor substrate over which nitride-containing hard mask layer 130 is deposited in step 702. At step 704, a mask layer is formed over the nitride layer. In process 700, the mask layer may be represented by photoresist layer 406, while the nitride layer may be represented by hard mask layer 130. At step 706, an opening is created through the mask layer and the nitride layer. At step 708, the nitride layer is exposed to an etch gas comprising tungsten. The exposure at step 708 may occur during DRIE as the etch path approaches low-k region 150-1. At step 710, the opening is extended with an etch process through the semiconductor substrate. The extension of the opening in step 710 may be enabled by the sidewall passivation of partial via 410 to form TSV 104 (see FIGS. 4D, 1A), for example, by tungsten nitride as a result of introducing tungsten additive to the etch gas, as described herein.

Turning now to FIG. 8, a process 800 of adding tungsten during through-substrate etching is shown in flowchart format. It is noted that some portions of process 800 may be omitted or rearranged in certain embodiments.

Process 800 may begin at step 802 by providing a plurality of layers, at least some of the layers comprising a mask layer, a nitride layer under the mask, and a silicon-containing layer under the nitride layer. In step 802, the mask layer may be represented by photoresist layer 406, the nitride layer may be represented by hard mask layer 130, while the silicon-containing layer may be represented by substrate 150. At step 804, an opening in the mask layer is defined. For example, at step 804, photoresist layer 406 may be exposed and developed to define one or more via openings. At step 806, the nitride layer is etched through the opening to define first sidewalls of the nitride layer. For example, sidewalls of partial via 310 shown in FIGS. 3B and 3C may be the first sidewalls in step 806. At step 808, the silicon-containing layer exposed in the opening is etched. The etching process at step 808 may be a Bosch or a non-Bosch etching process. The etching process at step 808 may employ DRIE in an anisotropic manner. At step 810, a tungsten nitride is formed on the first sidewalls of the nitride layer before or during etching of the silicon-containing layer. For example, etching in step 810 may include WF₆ additive for etch protection to the etch gas, as described herein.

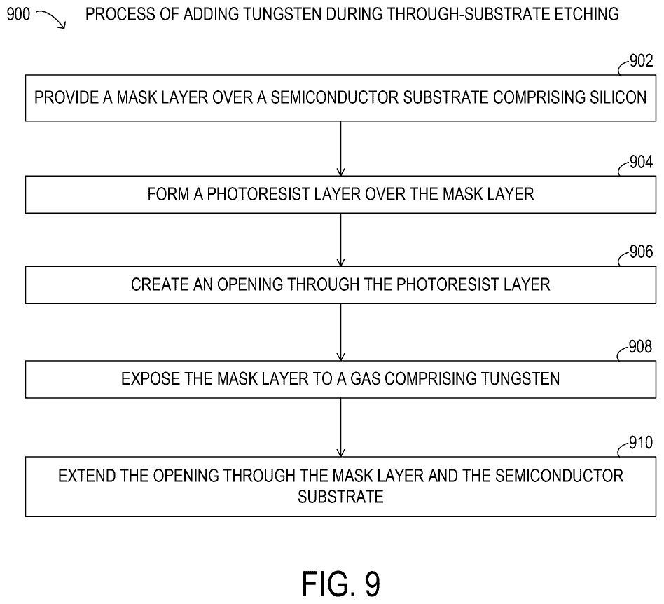

Turning now to FIG. 9, a process 900 of adding tungsten during through-substrate etching is shown in flowchart format. It is noted that some portions of process 900 may be omitted or rearranged in certain embodiments.

Process 900 may begin at step 902 by providing a mask layer overlaying a semiconductor substrate comprising silicon. In process 900, the mask layer may be represented by hard mask layer 130, while the semiconductor substrate may be represented by substrate 150. At step 904, a photoresist layer over the mask layer is formed. In process 900, the photoresist layer may be represented by photoresist layer 406. At step 906, an opening through the photoresist layer is created. At step 908, the mask layer is exposed to tungsten. At step 910, the opening is extended through the mask layer and the semiconductor substrate.

In a further aspect, a tungsten additive is added to a silicon etch process, such as for a high-aspect ratio Si etches that are used to fabricate various types of semiconductor devices, including TSVs and deep-trench isolation (DTI) structures, among others.

As noted above, the Bosch process commonly used for etching high-aspect ratio structures uses alternating cycles of an etch gas and a passivation gas and may be associated with certain undesirable features. In some cases, adverse outcomes in the profile of deep etched structures using the Bosch process can result, which is undesirable. An ideal profile is typically one with parallel or straight edge profiles of the remaining material in the high aspect ratio structure. In one example, a profile of the high-aspect ratio structure formed using the Bosch etch process can have a tapered shape that reduces in diameter or cross-sectional area along the etch path. The tapered shape resulting from the Bosch process may arise when the passivating layers are deposited in excess, thereby reducing or constraining the amount of desired material to be removed by etching. In this case the desired aspect ratio or etch depth may not be attained due to the tapered profile, which can be an undesired outcome. In another example, mask undercutting may occur at the Si-mask interface during Bosch process etching. In such cases of mask undercutting, the Si-mask interface is not properly passivated, whether from increased etching at the Si-mask interface or due to poor formation of the passivating layers, which are undesirable outcomes. In yet another example, a reversed tapered profile may result from the Bosch process that increases in diameter or cross-sectional area along the etch path. The reverse tapered shape from the Bosch process may occur when the passivating layers are insufficiently deposited such that too much material is etched away along the etch path. In such cases of reverse tapered profiles, the insufficient deposition of passivating layers may become worse as the aspect ratio increases, to longer depths along the etch path, in particular embodiments. When process controls during Bosch or other etch processes are insufficiently regulated in a tight window, the amount of passivation layer that is deposited may vary or secondary effects may occur that result in bowing of the etch profile in which the diameter or cross-sectional area of the etched structure varies, both positively and negatively, to an undesirable extent. As noted previously, another example of undesirable outcomes from the Bosch process include scalloping that can occur as a result of in situ alternation of the etch gas and the passivation gas, and results in an undesired high edge roughness of the etch profile.

To avoid problems such as discussed above, WF₆ is used as a passivating agent for high aspect ratio Si etch processes as a source of tungsten along with chlorine gas (Cl₂) used at an etchant gas. The use of WF₆ with Cl₂ in high aspect ratio Si etch processes can result in deposition of a passivating layer of tungsten (W) that can serve as a more robust protection layer than, for example, using octafluorocyclobutane (C₄F₈) polymer that is commonly used in Bosch processes. The use of WF₆ to deposit a passivating layer of tungsten can enable certain increases flexibility in processing options for high aspect ratio Si etches and can result in improved quality of etch profiles in the resulting structures, such as by avoiding the tapered profile, mask undercutting, the reverse tapered profile, bowing, and scalloping, as discussed above, among other undesirable outcomes. Another advantage with the use of WF₆ with Cl₂ for high aspect ratio Si etch processes, as described in further detail below, is that the gas species used have low global warming potential (GWP), while the use of per- and polyfluoroalkyl substances (PFAS), such as C₄F₈ is avoided.

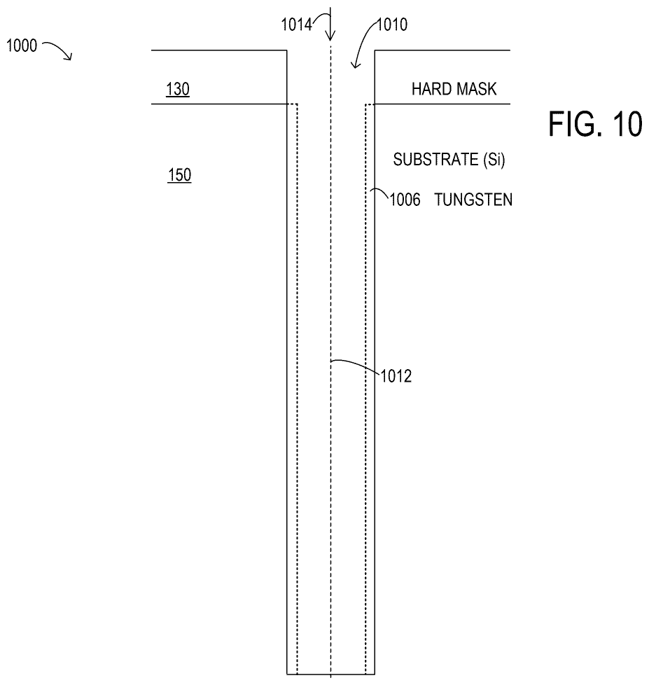

Referring now to FIG. 10, an etch profile 1000 depicted as a cross-sectional schematic illustration shows a semiconductor substrate device during an etch process along an etch path 1012 in an etch direction 1014, including a depiction of a W passivation layer 1006 in a process of Si etching using Cl₂ and WF₆, as described herein. In FIG. 10, the etch process may be performed with or without plasma enhancement, and may include DRIE in some embodiments. Accordingly, in etch profile 1000, Si substrate 150 is shown covered by hard mask 130, which has been patterned to provide an opening 1010 for a high aspect ratio structure.

As shown in FIG. 10, the use of WF₆ with Cl₂ in high aspect ratio Si etch resulting in deposition of passivation layer 1006 of tungsten (W) on Si substrate 150 can improve the anisotropy of the etch process that has a desirable outcome for etch profiles created in this manner. The element tungsten (W) is an effective passivant due to the low volatility of tungsten compounds in general. Since the deposition of W 1006 on Si is a replacement reaction, as explained below, the passivating layer formed displaces a Si surface layer, rather than become deposited on top of Si. As a result, W passivation can avoid the tapered profile shape that can occur when using SF₆ etchant with C₄F₈ polymer passivant, such as in the Bosch process.

The use of WF6 can occur with various types of etch processes and process conditions, such as being added in a primary etch step in a non-Bosch process, being used in a separate passivation step similar to a Bosch process, or ex situ in a chemical vapor deposition (CVD) step. In the non-Bosch process, WF₆ and Cl₂ can be combined and used concurrently in a single etch step and can improve anisotropy due to W passivation 1006 along etch path 1012. In a Bosch-like process, a partial etch of Si substrate 150 may be performed as a first step using Cl₂ etchant gas, followed by in situ treatment with WF₆ that can occur without plasma using CVD or with plasma using PECVD, such that WF₆ is periodically added while the Cl₂ etch is performed. These steps can be repeated along etch path 1012 until a desired etch depth is reached, such that a high degree of anisotropy, and correspondingly, a high quality etch profile is obtained along the duration of etch path 1012. In the ex situ CVD step, the partial etch of Si substrate 150 can be intermingled with WF₆ treatment in a CVD chamber to introduce WF₆ to the etch process.

The chemical reaction resulting in W deposition on Si is given by Reaction 6 below.

2WF₆(g)+3Si(s)→>2W(s)+3SiF₄(g) [Reaction 6]

As noted above, Reaction 6 is a displacement reaction that replaces Si with W in the presence of WF₆. Reaction 6 may exhibit self-protection from excessive removal of Si, since the formation of passivating layer 1006 of W covers the underlying surface of Si substrate 150, which then limits further consumption of Si. In this manner, Reaction 6 can result in a W layer 1006 with limited and relatively uniform thickness along etch path 1012. In one observation, W layer 1006 is deposited to a thickness of 15-20 nm independent of temperature. In another observation, a layer thickness l_{∞} of W layer 1006 is dependent on temperature and is given by an Arrhenius relationship defined in Equation 1.

$${l}_{∞} = {l}_{0} {e}^{\frac{E}{kT}} \qquad [ Equation 1 ]$$

A growth model for W layer 1006 based on Equation 1 describes the initial formation of W as a nearly closed surface but still having pores and grain boundaries at certain locations. In this state, Si can rapidly diffuse to and over the W surface to continue reacting with WF₆ as given by Reaction 6. As a result, a layer-by-layer growth of W layer 1006 occurs. The rate limiting factor is therefore the diffusion of Si to the surface. When the transport of Si abates and Reaction 6 cannot proceed, the reaction becomes limited to the pores where Si is still exposed, resulting in closing of the pores with W, effectively stopping further progress of Reaction 6 and forming the thickness l_{∞} of W layer 1006. The Arrhenius relationship of Equation 1 can describe the temperature dependency of the Si diffusion through the pores.

In yet a further observation by Leusink et al., the diffusion of WF6 to the surface of Si substrate 150 is slower than the Si diffusion to and over W layer 1006 and slower than Reaction 6. However, experiments performed at higher pressures of WF₆ result in thicknesses of W layer 1006 of 14 nm to 50 nm, whereas the model of Leusink predicts a thickness range of 7 nm to 140 nm. The empirical observation show that the concentration of WF₆ above the Si surface is likely a key factor and that an excess of WF₆ is the cause of the experimental results. Thus, instead of a layer-by-layer deposition, it is postulated that a reaction layer is formed that sustains the progress of Reaction 6, with the final states being gaseous SiF₄ and solid metallic W. By analyzing samples of W layer 1006 using mass spectroscopy and atomic emission spectroscopy (AES), certain insights into the mechanisms of Reaction 6 to deposit W layer 1006 can be gleaned. Initially, W grows in-depth into Si, while subsequent growth becomes dominated by lateral growth of W, resulting in a stabilization of the thickness of W at about 15-20 nm. Interestingly, in the outer 5 nm concentrations of Si and W appear homogenous. In these outer layers, Si concentration decreases exponentially with time as SiF₄ production increases exponentially, while Si is displaced with W. As the concentration of W reaches 100% in the outer layers, Reaction 6 stops and the deposited W layer 1006 serves as a diffusion barrier for Si. While the in-depth growth rate and the production rate of SiF₄ are strongly temperature dependent, the final layer thickness is temperature independent. The production rate of SiF4 is energy activated and the observed production rate of 10¹³/s corresponds to a typical first order surface process, indicating that SiF₄ is produced at the surface.

As disclosed herein, a process for adding tungsten during through-substrate etching includes forming a nitride layer over a semiconductor substrate, forming a mask layer over the nitride layer, creating an opening through the mask layer and the nitride layer, exposing the nitride layer to an etch gas comprising tungsten, and extending, with an etch process, the opening through the semiconductor substrate.

Example 1. A process includes forming a nitride layer over a semiconductor substrate; forming a mask layer over the nitride layer; creating an opening through the mask layer and the nitride layer; exposing the nitride layer to an etch gas including tungsten; and extending, with an etch process, the opening through the semiconductor substrate.

Example 2. The process of example 1, where the etch gas includes tungsten hexafluoride (WF6).

Example 3. The process of one of examples 1 or 2, where, after etching of the low-k region and during etching of the semiconductor substrate, the tungsten hexafluoride (WF6) is removed from the etch gas.

Example 4. The process of one of examples 1 to 3, where the etch gas further includes a halogen.

Example 5. The process of one of examples 1 to 4, where the etch gas further includes nitrogen.

Example 6. The process of one of examples 1 to 5, where the etch gas further includes silicon tetrafluoride (SiF4).

Example 7. The process of one of examples 1 to 6, where the nitride layer is exposed to the etch gas prior to etching of a low-k region of the semiconductor substrate.

Example 8. The process of one of examples 1 to 7, where the nitride layer is exposed to the etch gas during etching of the low-k region.

Example 9. The process of one of examples 1 to 8, further including: forming a layer of tungsten nitride over sidewalls of the nitride layer.

Example 10. The process of one of examples 1 to 9, where the etch process further includes repeating the following steps: etching using the etch gas for a first duration; and passivating using a polymer depositing gas for a second duration.

Example 11. The process of one of examples 1 to 10, where the etch process further includes: continuously etching using the etch gas with an anisotropic etch process.

Example 12. A process includes providing a plurality of layers, at least some of the layers including a mask layer, a nitride layer under the mask layer, and a silicon-containing layer under the nitride layer; defining an opening in the mask layer; etching the nitride layer through the opening to define first sidewalls of the nitride layer; etching the silicon-containing layer exposed in the opening; and forming a tungsten nitride layer on the first sidewalls of the nitride layer before or during the etching of the silicon-containing layer.

Example 13. The process of example 12, where etching the silicon-containing layer exposed in the opening further includes etching completely through the silicon-containing layer.

Example 14. The process of one of examples 12 or 13, where etching the nitride layer further includes exposing the nitride layer to a gas including tungsten hexafluoride (WF6).

Example 15. The process of one of examples 12 to 14, where the nitride layer is exposed to the gas prior to etching of the silicon-containing layer.

Example 16. The process of one of examples 12 to 15, where the nitride layer is exposed to the gas during etching of the silicon-containing layer.

Example 17. The process of one of examples 12 to 16, where, during etching of the silicon-containing layer, the tungsten hexafluoride (WF6) is removed from the gas.

Example 18. The process of one of examples 12 to 17, where the gas further includes nitrogen.

Example 19. The process of one of examples 12 to 18, where the gas further includes silicon tetrafluoride (SiF4).

Example 20. The process of one of examples 12 to 19, further including: forming a tungsten nitride on second sidewalls of the silicon-containing layer.

Example 21. A process includes providing a mask layer over a semiconductor substrate including silicon; forming a photoresist layer over the mask layer; creating an opening through the photoresist layer; exposing the mask layer to a gas including tungsten; and extending the opening through the mask layer and the semiconductor substrate.

Example 22. The process of example 21, where exposing the mask layer to the gas including tungsten and extending the opening further includes exposing the mask layer to the gas including tungsten hexafluoride (WF6) before or during etching of the semiconductor substrate, where, during etching of the semiconductor substrate, the tungsten hexafluoride (WF6) is removed from the gas.

Example 23. The process of one of examples 21 or 22, where exposing the mask layer to the gas including tungsten and extending the opening further includes: exposing the mask layer to the gas including tungsten hexafluoride (WF6) to deposit a tungsten (W) layer over the semiconductor substrate including silicon (Si).

Example 24. The process of one of examples 21 to 23, where exposing the mask layer to the gas including tungsten and extending the opening further includes: depositing the tungsten (W) layer while displacing or consuming at least some of the silicon (Si).

Example 25. The process of one of examples 21 to 24, where exposing the mask layer to the gas including tungsten and extending the opening further includes: depositing the tungsten (W) layer until a maximum thickness of the tungsten (W) layer is deposited, where after the maximum thickness of the tungsten (W) layer is deposited, the displacing or consuming at least some of the silicon (Si) automatically stops.

While the disclosure has been described with reference to illustrative embodiments, this description is not intended to be construed in a limiting sense. Various modifications and combinations of the illustrative embodiments, as well as other embodiments, will be apparent to persons skilled in the art upon reference to the description. It is therefore intended that the appended claims encompass any such modifications or embodiments.

What is claimed is:

1. A process comprising:
forming a nitride layer over a semiconductor substrate;
forming a mask layer over the nitride layer;
creating an opening through the mask layer and the nitride layer;
exposing the nitride layer to an etch gas comprising tungsten; and
extending, with an etch process, the opening through the semiconductor substrate.

2. The process of claim 1, wherein the etch gas comprises tungsten hexafluoride (WF₆).

3. The process of claim 2, wherein, after etching of a low-k region and during etching of the semiconductor substrate, the tungsten hexafluoride (WF₆) is removed from the etch gas.

4. The process of claim 1, wherein the etch gas further comprises a halogen.

5. The process of claim 4, wherein the etch gas further comprises nitrogen.

6. The process of claim 4, wherein the etch gas further comprises silicon tetrafluoride (SiF₄).

7. The process of claim 4, wherein the nitride layer is exposed to the etch gas prior to etching of a low-k region of the semiconductor substrate.

8. The process of claim 1, wherein the nitride layer is exposed to the etch gas during etching of the low-k region.

9. The process of claim 1, further comprising:
forming a layer of tungsten nitride over sidewalls of the nitride layer.

10. The process of claim 1, wherein the etch process further comprises repeating the following steps:
etching using the etch gas for a first duration; and
passivating using a polymer depositing gas for a second duration.

11. The process of claim 1, wherein the etch process further comprises:
continuously etching using the etch gas with an anisotropic etch process.

12. A process comprising:
providing a plurality of layers, at least some of the layers comprising a mask layer, a nitride layer under the mask layer, and a silicon-containing layer under the nitride layer;
defining an opening in the mask layer;
etching the nitride layer through the opening to define first sidewalls of the nitride layer;
etching the silicon-containing layer exposed in the opening; and
forming a tungsten nitride layer on the first sidewalls of the nitride layer before or during the etching of the silicon-containing layer.

13. The process of claim 12, wherein etching the silicon-containing layer exposed in the opening further comprises etching completely through the silicon-containing layer.

14. The process of claim 12, wherein etching the nitride layer further comprises exposing the nitride layer to a gas comprising tungsten hexafluoride (WF6).

15. The process of claim 14, wherein the nitride layer is exposed to the gas prior to etching of the silicon-containing layer.

16. The process of claim 14, wherein the nitride layer is exposed to the gas during etching of the silicon-containing layer.

17. The process of claim 16, wherein, during etching of the silicon-containing layer, the tungsten hexafluoride (WF₆) is removed from the gas.

18. The process of claim 14, wherein the gas further comprises nitrogen.

19. The process of claim 14, wherein the gas further comprises silicon tetrafluoride (SiF₄).

20. The process of claim 12, further comprising:
forming a tungsten nitride on second sidewalls of the silicon-containing layer.

21. A process comprising:
providing a mask layer over a semiconductor substrate comprising silicon;
forming a photoresist layer over the mask layer;
creating an opening through the photoresist layer;
exposing the mask layer to a gas comprising tungsten; and
extending the opening through the mask layer and the semiconductor substrate.

22. The process of claim 21, wherein exposing the mask layer to the gas comprising tungsten and extending the opening further comprises exposing the mask layer to the gas including tungsten hexafluoride (WF₆) before or during etching of the semiconductor substrate, wherein, during etching of the semiconductor substrate, the tungsten hexafluoride (WF₆) is removed from the gas.

23. The process of claim 21, wherein exposing the mask layer to the gas comprising tungsten and extending the opening further comprises:
exposing the mask layer to the gas including tungsten hexafluoride (WF₆) to deposit a tungsten (W) layer over the semiconductor substrate comprising silicon (Si).

24. The process of claim 23, wherein exposing the mask layer to the gas comprising tungsten and extending the opening further comprises:
depositing the tungsten (W) layer while displacing or consuming at least some of the silicon (Si).

25. The process of claim 24, wherein exposing the mask layer to the gas comprising tungsten and extending the opening further comprises:
depositing the tungsten (W) layer until a maximum thickness of the tungsten (W) layer is deposited, wherein after the maximum thickness of the tungsten (W) layer is deposited, the displacing or consuming at least some of the silicon (Si) automatically stops.
